(19) United States
(12) Patent Application Publication
(10) Pub. No.: US 2006/0255392 A1
(43) Pub. Date: Nov. 16, 2006

(54) Transistor including metal-insulator transition material and method of manufacturing the same

(75) Inventors: Choong-Rae Cho, Gimhae-Si (KR); In-Kyeong Yoo, Suwon-si (KR); Yang-Kyu Choi, Daejeon-si (KR); Sung-Il Cho, Boryeong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/432,620

(22) Filed: May 12, 2006

(30) Foreign Application Priority Data
May 12, 2005 (KR) 10-2005-0039726

(51) Int. Cl. H01L 29/94

(52) U.S. Cl. 257/310

(57) ABSTRACT

A transistor including a metal-insulation transition material and a method of manufacturing the same. The transistor including a metal-insulator transition material may include a substrate, a insulation layer formed on the substrate, a source region and a drain region separately formed from each other on the insulation layer, a tunneling barrier layer formed on at least one surface of the source region and the drain region, a metal-insulator transition material layer formed on the tunneling barrier layer and the insulation layer, a dielectric layer stacked on the metal-insulator transition material layer, and a gate electrode layer formed on the dielectric layer.

### PRIORITY STATEMENT

This application claims the benefit of Korean Patent Application No. 10-2005-0039726, filed on May 12, 2005, in the Korean Intellectual Property Office, the disclosure of which is incorporated herein in its entirety by reference.

### BACKGROUND OF THE INVENTION

1. Field of the Invention

Example embodiments of the present invention relate to a semiconductor device and a method of manufacturing the same, and more particularly, to a transistor including a metal-insulation transition material, in which a tunneling barrier layer is formed between a source region and a drain region in order to reduce a leakage current, and methods of operating and manufacturing the same.

2. Description of the Related Art

As semiconductor technology has developed, more highly integrated semiconductor devices are increasingly in demand. To more highly integrate a semiconductor device, it may be necessary to reduce the size of a field effect transistor (FET) therein. However, one or more technical problems may occur.

The smaller a field effect transistor (FET) is, the shorter a channel length between a source region and a drain region is, thereby potentially causing a short channel effect. The short channel effect may reduce a threshold voltage of the FET and/or reduce carrier mobility. In addition, if the transistor is smaller, channel resistance may be higher in an ‘ON’ state. Therefore, the amount of electric current that can be supplied may be restricted and the transistor's usefulness in a semiconductor device, for example, a phase-change random access memory (PRAM), a resistance random access memory (RRAM), or a magnetic random access memory (MRAM), may be limited.

A general complementary metal-oxide semiconductor (CMOS) has a threshold voltage greater than a given value to reduce or minimize a leakage current caused by thermal electrons. In addition, an operating voltage may need to be high enough to obtain a desired gain. Therefore, an increase of the degree of integration may be difficult because of the increase of power consumption and/or heating.

Methods for increasing capacitance of a gate insulation layer to reduce the size of a semiconductor device have been developed to overcome a leakage current problem that occurs when a device is small and a gate insulation layer is thin. In particular, research into the development of high-k materials has been conducted. On the other hand, if capacitance of a gate insulation layer increases, more time and/or active energy may be required to charge it. Consequently, the increase of the capacitance of a gate insulation layer may cause problems, for example, heat generation and a reduction in speed. However, if the capacitance is lower, a device may become less reliable, due to a leakage current.

### SUMMARY OF THE INVENTION

Example embodiments of the present invention provide a transistor having a metal-insulation transition material to reduce or minimize a short channeling effect, which may reduce a leakage current by forming a tunneling barrier layer between a source region and a dielectric layer, and which may be operated with a lower voltage.

Example embodiments of the present invention also provide a method of manufacturing a transistor as described above.

According to an example embodiment of the present invention, there is provided a transistor including a metal-insulator transition material, the transistor including a substrate; a insulation layer formed on the substrate; a source region and a drain region separately formed from each other on the insulation layer; a tunneling barrier layer formed on at least one surface of the source region and the drain region; a metal-insulator transition material layer formed on the tunneling barrier layer and the insulation layer; a dielectric layer stacked on the metal-insulator transition material layer; and a gate electrode layer formed on the dielectric layer.

In an example embodiment, the metal-insulator transition material layer may be changed from metal to insulator or vice versa according to a potential difference between the source region and the drain region.

In an example embodiment, the metal-insulator transition material layer may be formed of one selected from the group consisting of a chalcogenide material, a transition metal oxide, a composite material having a plurality of transition metal oxides, an aluminum oxide (Al₂O₃), and a composite material having a plurality of aluminum oxides (Al₂O₃).

In an example embodiment, a transition metal in the transition metal oxide may be selected from the group consisting of Ti, V, Fe, Ni, Nb, and Ta.

In an example embodiment, the dielectric layer may be formed of one of Al₂O₃, HfO₂, and ZrO₂.

In an example embodiment, the source region and the drain region may be formed of one of a metal film and a silicide film each of which may form a schottky junction with the metal-insulator transition material layer.

In an example embodiment, the metal film may be formed of one of Al, Ti, and Au.

In an example embodiment, the silicide film may be formed of one of platinum silicide (PtSi) and nickel silicide (NiSi₂).

In an example embodiment, the tunneling barrier layer may be formed of one of oxides and nitrides.

According to another example embodiment of the present invention, there is provided a method of manufacturing a transistor including a metal-insulator transition material, the method including forming an insulation layer on a substrate; forming a source region and a drain region separately from each other on the insulation layer; forming a tunneling barrier layer on at least one surface of the source region and the drain region; and sequentially stacking a metal-insulator transition material layer, a dielectric layer, and a gate electrode layer on the tunneling barrier layer and the insulation layer.

In an example embodiment, the method may further include exposing portions of the source region and the drain region by sequentially etching portions of the gate electrode layer, the dielectric layer, and the metal-insulator transition material layer.

In an example embodiment, the forming of the source region and the drain region separately from each other on the insulation layer may include forming a mask which exposes a region where the source region and the drain region of the insulation layer are to be formed; forming a conductive material layer on the exposed region of the insulation layer; and removing the mask.

In an example embodiment, the metal-insulator transition material layer may be formed of one selected from the group consisting of a chalcogenide material, a transition metal oxide, a composite material having a plurality of transition metal oxides, an aluminum oxide (Al₂O₃), and a composite material having a plurality of aluminum oxides (Al₂O₃).

In an example embodiment, a transition metal in the transition metal oxide may be selected from the group consisting of Ti, V, Fe, Ni, Nb, and Ta.

In an example embodiment, the tunneling barrier layer may be formed of one of an oxide formed by oxidizing surfaces of the source region and the drain region and a nitride by nitriding surfaces of the source region and the drain region.

In an example embodiment, the tunneling barrier layer may be formed by applying an insulation material to the insulation layer and the source region and the drain region.

### BRIEF DESCRIPTION OF THE DRAWINGS

The above and other features and advantages example embodiments of the present invention will become more apparent by describing in detail example embodiments thereof with reference to the attached drawings in which:

FIG. 1 is a cross-sectional view of a transistor using a metal-insulator transition material according to an example embodiment of the present invention;

FIG. 2 is a graph illustrating an electrical characteristic of a transistor using a metal-insulator transition material according to an example embodiment of the present invention;

FIGS. 3A and 3B are equivalent circuit diagrams of ‘ON’ and ‘OFF’ states of a transistor using a metal-insulator transition material according to an example embodiment of the present invention; and

FIGS. 4A through 4F illustrate stages in a method of manufacturing a transistor using a metal-insulator transition material according to an example embodiment of the present invention.

### DETAILED DESCRIPTION OF EXAMPLE EMBODIMENTS OF THE INVENTION

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words are used to denote one or more compounds but may also just indicate a single compound.

Now, in order to more specifically describe example embodiments of the present invention, various embodiments of the present invention will be described in detail with reference to the attached drawings. However, the present invention is not limited to the example embodiments, but may be embodied in various forms. In the figures, if a layer is formed on another layer or a substrate, it means that the layer is directly formed on another layer or a substrate, or that a third layer is interposed therebetween. In the following description, the same reference numerals denote the same elements.

Although the example embodiments of the present invention have been disclosed for illustrative purposes, those skilled in the art will appreciate that various modifications, additions and substitutions are possible, without departing from the scope and spirit of the invention as disclosed in the accompanying claims.

Hereinafter, the present invention will be described more fully with reference to the accompanying drawings, in which example embodiments of the invention are shown. In the drawings, the sizes and thicknesses of layers and regions are exaggerated for clarity.

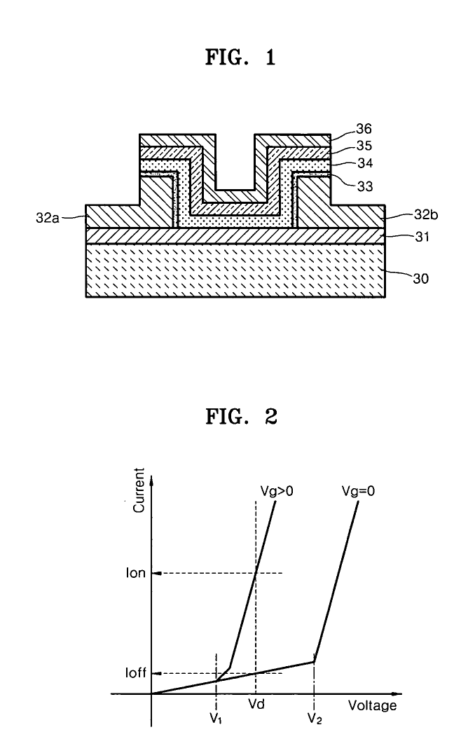

FIG. 1 is a cross-sectional view of a transistor using a metal-insulator transition material according to an example embodiment of the present invention. Referring to FIG. 1, an insulation layer 31 may be formed on a substrate 30. First and second conductive patterns 32a and 32b may be formed on the insulation layer 31, and may be separate from each other. One of the first and second conductive patterns 32a and 32b may be used as a source region and the other may be used as a drain region. Hereinafter, the first conductive pattern 32a is referred as a source region and the second conductive pattern 32b is referred to as a drain region. A tunneling barrier layer 33 may be formed on each of the source region 32a and the drain region 32b. A metal-insulator transition material layer 34, a dielectric layer 35, and a gate electrode layer 36 may be sequentially formed on the tunneling barrier layer 33 and the insulation layer 31.

Hereinafter, example materials of the layers in FIG. 1 will be described in more detail. The substrate 30 may be a semiconductor substrate doped with dopants, for example, a silicon substrate doped with n-type dopants or p-type dopants. The insulation layer 31 may be a thermal oxide film, for example, a SiO₂ film, a HfO₂ film, a SiNx film, etc. The source region 32a and the drain region 32b may be formed of metals or silicides. Aluminum (Al), titanium (Ti), or gold (Au), etc. may be used as the metal. Platinum silicide (PtSi) or nickel silicide (NiSi2), etc. may be used as the silicide.

The tunneling barrier layer 33 formed on each of the source region 32a and the drain region 32b may generally be formed of an insulation material. The insulation material may have a different composition from the source region 32a and the drain region 32b. The insulation material may include oxides or nitrides formed by oxidizing/nitriding surfaces of the source region 32a and the drain region 32b. For example, when the source region 32a and the drain region 32b are formed of aluminum (Al), the tunneling barrier layer 33 may be formed of aluminum oxide (Al₂O₃).

The metal-insulator transition material layer 34 may be formed of a chalcogenide material, a transition metal oxide, a composite material having a plurality of transition metal oxides, an aluminum oxide (Al₂O₃) or a composite material having a plurality of aluminum oxides (Al₂O₃). The transition metal may be, for example, Ti, V, Fe, Ni, Nb, or Ta.

The dielectric layer 35 may have a low reactivity with the metal-insulator transition material layer 34, for example, an Al₂O₃ film, a HfO₂ film, or a ZrO₂ film. The gate electrode layer 36 may be formed of, for example, Au, Pt, and Al, which may be generally used to form gate electrodes of a transistor.

Operation of the transistor of FIG. 1 will now be described. When a gate voltage Vg applied to the gate electrode layer 36 is maintained at 0V, and a potential difference Vd between the source region 32a and the drain region 32b is maintained to be lower than a threshold voltage Vth between the source region 32a and the drain region 32b, i.e., Vd<Vth, the metal-insulator transition material layer 34 formed between the source region 32a and the drain region 32b displays semiconducting or insulating characteristics. Accordingly, a channel is not formed between the source region 32a and the drain region 32b.

When the gate voltage Vg applied to the gate electrode layer 36 is maintained at 0V, and the potential difference Vd between the source region 32a and the drain region 32b is maintained to be higher than the threshold voltage Vth between the source region 32a and the drain region 32b, i.e., Vd>Vth, the metal-insulator transition material layer 34 formed between the source region 32a and the drain region 32b displays metallic characteristics. Accordingly, a channel is formed between the source region 32a and the drain region 32b and an electric current flows between the source region 32a and the drain region 32b.

When the gate voltage Vg applied to the gate electrode layer 36 is greater than 0V, a density of holes increases in adjacent regions of the metal-insulator transition material layer 34 to the source region 32a and the drain region 32b. Accordingly, a channel is formed in the metal-insulator transition material layer 34 formed between the source region 32a and the drain region 32b, and an electric current flows between the source region 32a and the drain region 32b even when the potential difference Vd between the source region 32a and the drain region 32b is lower than the threshold voltage Vth between the source region 32a and the drain region 32b, i.e., Vd<Vth. Therefore, when the gate voltage Vg applied to the gate electrode layer 36 is greater than 0V, the threshold voltage Vth between the source region 32a and the drain region 32b decreases.

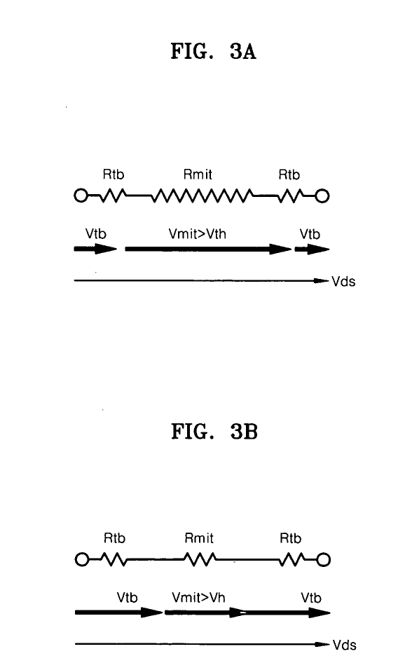

FIG. 2 is a graph illustrating an electrical characteristic of a transistor using a metal-insulator transition material according to an example embodiment of the present invention. Referring to FIG. 2, electric current flowing between the source region 32a and the drain region 32b increases when the potential differences Vd between the source region 32a and the drain region 32b are both V1 and V2. Here, when the potential difference Vd between the source region 32a and the drain region 32b is V1, the gate voltage Vg applied to the gate electrode layer 36 is greater than 0V. When the potential difference Vd between the source region 32a and the drain region 32b is V2, the gate voltage Vg applied to the gate electrode layer 36 is equal to 0V. The increase of the current flowing between the source region 32a and the drain region 32b when the potential differences Vd between the source region 32a and the drain region 32b is V1 is due to a lower threshold voltage Vth caused by applying a gate voltage Vg greater than 0V. Accordingly, when the potential difference Vd between the source region 32a and the drain region 32b is maintained in the range of V1 to V2, the gate voltage Vg greater than 0V is applied to the gate electrode layer 36, thereby causing an ‘ON’ state. Otherwise, when the potential difference Vd between the source region 32a and the drain region 32b is maintained in the range of V1 to V2, the gate voltage Vg equal to 0V is applied to the gate electrode layer 36, thereby causing an ‘OFF’ state. That is, a switching operation may be performed.

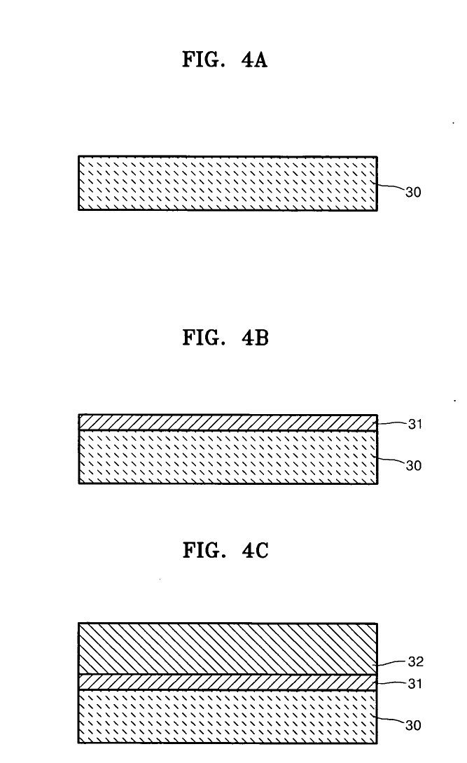

As semiconductor devices become increasingly integrated, their resistivity also increases, and thus heating in the device may become a problem. For example, even when the gate voltage Vg applied to the gate electrode layer 36 is maintained at 0V, and the potential difference Vd between the source region 32a and the drain region 32b is maintained to be lower than the threshold voltage Vth between the source region 32a and the drain region 32b, i.e., Vd<Vth, a current can flow through the metal-insulator transition material layer 34. This is verified by a gradual increase of Ioff, as illustrated in FIG. 2. Accordingly, Ioff may be decreased by forming the tunneling barrier layers 33 between the metal-insulator transition material layer 34 and the source region 32a, and between the metal-insulator transition material layer 34 and the drain region 32b. FIG. 3A illustrates an equivalent circuit corresponding to a channel region formed of the tunneling barrier layer 33 and the metal-insulator transition material layer 34, the tunneling barrier layer 33 being in an ‘ON’ state according to an example embodiment of the present invention. FIG. 3B illustrates an equivalent circuit corresponding to the channel region formed of the tunneling barrier layer 33 and the metal-insulator transition material layer 34, the tunneling barrier layer 33 being in an ‘OFF’ state according to an example embodiment of the present invention.

Referring to FIG. 3A, the metal-insulator transition material layer 34 displays metallic characteristics in the ‘ON’ state, so therefore its resistivity Rmit decreases. Accordingly, a large amount of voltage is applied to the tunneling barrier layer 33. Simultaneously, the resistivity of the tunneling barrier layer 33 decreases, and a voltage Vmit greater than the holding voltage Vh is applied to the metal-insulator transition material layer 34.

Referring to FIG. 3B, the metal-insulator transition material layer 34 displays insulating characteristics in the ‘OFF’ state, so therefore its resistivity Rmit increases. Because most of the voltage Vmit is applied to the metal-insulator transition material layer 34 having higher resistivity, carrier movement through the tunneling barrier layer 33 may be effectively reduced or prevented.

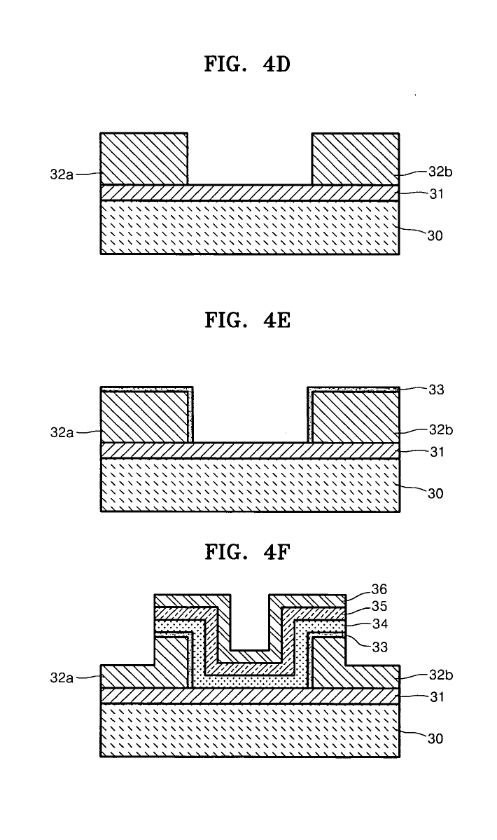

Hereinafter, referring to FIGS. 4A through 4F, a method of manufacturing a transistor using a metal-insulator transition material according to an example embodiment of the present invention will be described in detail.

Referring to FIGS. 4A through 4D, an insulation layer 31 may be formed on a substrate 30. A conductive material 32 is applied to the insulation layer 31, and then patterned to form a source region 32a and a drain region 32b using conventional photographic and etching processes. Alternatively, a lift-off method may be applied, in that, an exposure film pattern (not illustrated) may be formed on the insulation layer 31 between the source region 32a and the drain region 32b, a conductive layer is stacked at positions where the source region 32a and the drain region 32b will be formed, and then the exposure film pattern is removed. The source region 32a and the drain region 32b may be formed of metals or silicides. Aluminum (Al), titanium (Ti), or gold (Au), etc. may be used as the metal. Platinum silicide (PtSi) or nickel silicide (NiSi₂), etc. may be used as the silicide.

Referring to FIG. 4E, a tunneling barrier layer 33 may be formed on one or both of the source region 32a and the drain region 32b. The tunneling barrier layer 33 may be formed by oxidizing surfaces of the source region 32a and the drain region 32b. For example, when the source region 32a and the drain region 32b are formed of Al, Ti, or Ta, the tunneling barrier layer 33 may be formed by oxidizing Al, Ti, or Ta to form Al₂O₃, TiO₂, or Ta₂O₅, respectively. Alternatively, another insulation oxide or nitride material may be applied to the source region 32a and the drain region 32b to form the tunneling barrier layer 33.

Referring to FIG. 4F, a metal-insulator transition material layer 34 may be formed on the insulation layer 31, the source region 32a, and the drain region 32b by applying a metal-insulator transition material. The metal-insulator transition material layer 34 may be changed from metal to insulator or vice versa according to a potential difference between the source region 32a and the drain region 32b. The metal-insulator transition material layer 34 may be formed of a chalcogenide material, a transition metal oxide, or a composite material having a plurality of transition metal oxides. The transition metal may be, for example, Ti, V, Fe, Ni, Nb, or Ta. In addition, the metal-insulator transition material layer 34 may be formed of an aluminum oxide (Al₂O₃) or a composite material having a plurality of aluminum oxides (Al₂O₃).

A dielectric layer 35 and a gate electrode layer 36 may be sequentially formed on the metal-insulator transition material layer 34. The dielectric layer 35 may have a lower reactivity with the metal-insulator transition material layer 34 and may be formed as a thin film. The dielectric layer 35 may be formed of, for example, Al₂O₃, HfO₂, or ZrO₂. The gate electrode layer 36 may be formed on the dielectric layer 35.

In addition, an exposure film pattern PR (not illustrated) may be formed on the gate electrode layer 36, and an exposed region of the gate electrode 35 may be etched using the exposure film pattern PR as a mask. During the etching process, patterns of the source region 32a and the drain region 32b may be exposed and their area may be limited. In addition, the exposure film pattern PR may be removed after etching, and thus the structure of the transistor of FIG. 1 may be obtained.

The insulation layer 31 may be formed using a surface oxidizing process on the substrate 30. The metal-insulator transition material layer 34 may be formed only between the source region 32a and the drain region 32b.

In example embodiments, the metal-insulator transition material layer 34 may be made of a transition metal oxide having multiple resistance states, as described above. For example, the metal-insulator transition material layer 34 may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The metal-insulator transition material layer 34 may be a chemical compound including one or more elements selected from the group consisting of S, Se, Te, As, Sb, Ge, Sn, In and Ag.

In some example embodiments, the metal-insulator transition material layer 34 may include chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the metal-insulator transition material layer 34 may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the metal-insulator transition material layer 34 may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the metal-insulator transition material layer 34 is described above as being formed primarily of ternary phase-change chalcogenide alloys, the chalcogenide alloy of the metal-insulator transition material layer 34 could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

As described above, a transistor according to example embodiments of the present invention, which has a tunneling barrier layer formed between the metal-insulator transition material layer and the source and drain regions, may reduce a leakage current and/or provide more stable operation. In addition, a transistor according to example embodiments of the present invention may reduce or minimize heat generation due to lower operating voltage, therefore enhancing the integration degree of semiconductor devices.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A transistor including a metal-insulator transition material, the transistor comprising:
a substrate;
a insulation layer formed on the substrate;
a source region and a drain region separately formed from each other on the insulation layer;
a tunneling barrier layer formed on at least one surface of the source region and the drain region;
a metal-insulator transition material layer formed on the tunneling barrier layer and the insulation layer;
a dielectric layer stacked on the metal-insulator transition material layer; and
a gate electrode layer formed on the dielectric layer.

2. The transistor of claim 1, wherein the metal-insulator transition material layer is changed from metal to insulator or vice versa according to a potential difference between the source region and the drain region.

3. The transistor of claim 1, wherein the metal-insulator transition material layer is formed of one selected from the group consisting of a chalcogenide material, a transition metal oxide, a composite material having a plurality of transition metal oxides, an aluminum oxide (Al₂O₃), and a composite material having a plurality of aluminum oxides (Al₂O₃).

4. The transistor of claim 3, wherein a transition metal in the transition metal oxide is selected from the group consisting of Ti, V, Fe, Ni, Nb, and Ta.

5. The transistor of claim 1, wherein the dielectric layer is formed of one of Al₂O₃, HfO₂, and ZrO₂.

6. The transistor of claim 1, wherein the source region and the drain region are formed of one of a metal film and a silicide film, each of which forms a schottky junction with the metal-insulator transition material layer.

7. The transistor of claim 6, wherein the metal film is formed of one of Al, Ti, and Au.

8. The transistor of claim 6, wherein the silicide film is formed of one of platinum silicide (PtSi) and nickel silicide (NiSi₂).

9. The transistor of claim 1, wherein the tunneling barrier layer is formed of one of oxides and nitrides.

10. A method of manufacturing a transistor including a metal-insulator transition material, the method comprising:
forming an insulation layer on a substrate;
forming a source region and a drain region separate from each other on the insulation layer;
forming a tunneling barrier layer on at least one surface of the source region and the drain region; and
sequentially stacking a metal-insulator transition material layer, a dielectric layer, and a gate electrode layer on the tunneling barrier layer and the insulation layer.

11. The method of claim 10 further comprising:
exposing portions of the source region and the drain region by sequentially etching portions of the gate electrode layer, the dielectric layer, and the metal-insulator transition material layer.

12. The method of claim 10, wherein forming the source region and the drain region separate from each other on the insulation layer includes:
forming a mask which exposes a region where the source region and the drain region of the insulation layer are to be formed;
forming a conductive material layer on the exposed region of the insulation layer; and
removing the mask.

13. The method of claim 10, wherein the metal-insulator transition material layer is formed of one selected from the group consisting of a chalcogenide material, a transition metal oxide, a composite material having a plurality of transition metal oxides, an aluminum oxide (Al₂O₃), and a composite material having a plurality of aluminum oxides (Al₂O₃).

14. The method of claim 13, wherein a transition metal in the transition metal oxide is selected from the group consisting of Ti, V, Fe, Ni, Nb, and Ta.

15. The method of claim 10, wherein forming tunneling barrier layer includes at least one of forming an oxide by oxidizing surfaces of the source region and the drain region and forming a nitride by nitriding the surfaces of the source region and the drain region.

16. The method of claim 10, wherein forming tunneling barrier layer includes applying an insulation material to the insulation layer, the source region and the drain region.
